(19) United States
(12) Patent Application Publication
(10) Pub. No.: US 2003/0034557 A1
(43) Pub. Date: Feb. 20, 2003

(54) Chip carrier for a semiconductor chip module

(76) Inventors: Prem Swarup Gupta, Lake Hiawatha, NJ (US); Edward Curtis Douglas, Flemington, NJ (US)

Correspondence Address: PENNIE AND EDMONDS, 1155 AVENUE OF THE AMERICAS, NEW YORK, NY, 100362711

(21) Appl. No.: 09/931,436

(22) Filed: Aug. 16, 2001

(51) Int. Cl. H01L 23/06

(52) U.S. Cl. 257/729

(57) ABSTRACT

A chip carrier has a cavity portion for receiving a semiconductor chip and a flange portion along at least a portion of a top perimeter of the cavity portion. The module preferably includes a substrate (e.g., a PCB or chip carrier substrate) having a slot for receiving the cavity portion of the chip carrier, with the flange portion of the chip carrier being supported by the substrate. The flange portion is preferably electrically conductive and grounded, so that appropriate conductive pads on the chip can be wire bonded to the flange, while other on-chip pads can be wire bonded to designated pads on the substrate surface.. The cavity portion is also preferably thermally conductive to provide a thermal path for the semiconductor chip. In another embodiment, a relatively thick flanged chip mounting pad is also received within a substrate slot to provide improved heat dissipation.

### FIELD OF INVENTION

The present invention relates to the field of integrated circuit and semiconductor packaging and, more particularly, to a chip carrier or package for housing a semiconductor chip in a semiconductor chip module.

### BACKGROUND OF THE INVENTION

A semiconductor chip (or die) is a bare, unpackaged semiconductor device that has been cut from a wafer and typically comprises one or more integrated circuits. Chip modules are subsystems that include one or more chips and are designed to act as a building blocks for more complex circuits. Within a module, chips are connected in an initial level of “off-chip” electrical connections. Different modules may then be connected to one another in a second level of connections. Modules are often interconnected on a “next-level” circuit substrate, commonly a printed circuit board (PCB) or the like. A PCB typically comprises a base or substrate of insulating material with a conductive pattern on its surface.

A single-chip module is a dedicated packaging module for a particular semiconductor chip and serves to protect the chip from the external environment and facilitate attachment to a next-level substrate. A multi-chip module (MCM), on the other hand, contains two or more chips that are typically mounted on a common module substrate, and the MCM substrate may then be mounted to a next level substrate.

In chip-on-board technology, a semiconductor chip is directly attached to a circuit substrate without first being housed in a dedicated packaging module. Chip-on-board technology may be used, for example, to connect a chip to a MCM substrate. An adhesive material such as epoxy is typically used to attach or bond the chip to the substrate. Conductive pads on the chip (e.g., on the top surface of the chip) are usually bonded to conductive pads on the circuit substrate using fine wires. Alternatively, an unpackaged chip with conductive pads formed on its top surface may be directly “flip-chip” connected to spatially corresponding pads on the circuit substrate's surface, in flip-chip-on-board technology. In this case, the conductive pads on the chip are solder-connected directly to the conductive pads on the substrate surface. Reliability concerns often arise in flip-chip-on-board technology; for instance, due to a mismatch in the coefficients of thermal expansion between the semiconductor chip and the substrate, the solder joints may fatigue. (Although an epoxy based underfill material may be used between the chip and the substrate to attempt to lessen the thermal fatigue, this may lead to “bleed out” problems, as described below.) Once a chip is attached and electrically connected to the substrate—using wire or flip-chip connections—it is typically glob-top molded with an encapsulant material to protect the chip and the connections.

In contrast, in a single-chip module, a chip is housed in a dedicated package that better protects the chip from the external environment and facilitates connections of the packaged chip to a next-level substrate. Conventional single-chip packaging modules typically comprise a plastic or ceramic housing that surrounds the chip. Inside the package, the first level of off-chip connections are made from conductive points on the chip to internal bonding pads within the package. These off-chip connections may be made by wire or, alternatively, in flip-chip carrier technology, pads or bumps on the chip may be solder-attached directly to the package substrate to provide both an electrical and a mechanical connection. The internal bonding pads of the package are then electrically connected to external terminals of the package, e.g., through a package substrate. In a second level of connections, the external terminals can be electrically and mechanically connected to the next level substrate using through-hole mounting or surface mounting techniques.

A chip carrier is a compact chip package having a relatively low profile and a chip mounting area that generally occupies a major part of the package's overall footprint. Prior art chip carrier packages, and in particular their chip mounting areas, are typically constructed from a base sheet of plastic or ceramic, such as alumina. Leaded chip carriers have leads that are attached to the side of the carrier and usually surface mounted onto a next-level substrate. Leadless chip carriers do not have electrical leads, but instead have solder balls, lands, or bumps located on the outside of the carrier package. For example, leadless chip carriers often have metallized I/O connections, such as a ball grid array (BGA), along the bottom surface of the carrier package. In this case, the leadless chip carrier can be surface mounted onto a next level substrate by placing the carrier onto contact pads that mirror those of the chip carrier. An electrical and mechanical connection may subsequently be provided by soldering the electrical terminals of the chip carrier to the substrate.

For example, Andrews et al. in U.S. Pat. No. 4,147,889 disclose a chip carrier formed from a thin dielectric base material formed into a dish shape to provide a receptacle. A chip is placed in the receptacle on top of an internal heat sink layer, and conductive pads on the chip are electrically connected to corresponding conductive traces on the bottom surface of the receptacle. The dielectric base material also provides a series of flange sections around the receptacle's rim, and these are used to mount the inverted receptacle base to a circuit board. The conductive traces on the bottom surface of the receptacle run along the inner part of the receptacle and then along the flanges before terminating at conductive pads near the flange edges. The conductive pads on the inner flange surface are then electrically connected to circuit paths on the circuit board when the carrier is mounted onto the circuit board. The outside of the receptacle and flanges is covered with a copper backing to provide an external heat sink and act as an electrical shield.

Fuller Jr. et al. in U.S. Pat. No. 5,784,260 disclose a chip carrier with a dielectric substrate having an opening formed within it. A copper heat sink is formed on the bottom surface of the substrate and thereby forms a chip-receiving well with the opening. Bonding pads on the upper surface of the substrate are connected by wires to a chip, before a plastic encapsulant is applied over the chip and wire connections.

Similarly, Bourdelaise et al. in U.S. Pat. No. 5,027,191 disclose a chip carrier formed from an electrically insulating material and having a cavity in which a chip is mounted. Wires from the chip extend to at least one bonding ledge having an outer surface and extending from the floor of the cavity along a cavity wall. To shorten the length of wires from the chip to traces on a first bonding ledge, the height of the bonding ledge from the cavity floor is made very close to the height of the chip from the cavity floor.

However, both single-chip modules (such as the prior art chip carriers described above) and chips attached to circuit substrate using chip-on-board technology may suffer from one or more potential problems.

First, although it is convenient to use wires to connect conductive pads from the chip to conductive pads on a circuit board or inside a carrier package, these wires may adversely affect and interfere with the performance of high frequency IC devices. In known manner, the electrical parasitics (principally inductance) generated by such wires increase with the length of the wires. Although Bourdelaise et al., for example, try to minimize these undesirable effects by providing ledges along a cavity side wall, the resulting design is complex, generally requiring ledges of different heights to enable a sufficiently small pitch to be achieved between wire bond connections from the chip.

Second, in chip-on-board connections that use an adhesive material to secure the chip to the board, the adhesive material may not, on its own, provide an adequately efficient thermal path to conduct heat generated by the chip into the PCB. Chip carriers and chip packages, which as mentioned have chip mounting areas that are typically formed of a dielectric base material, also may not provide an adequate heat conduction path to carry heat away from the chip conveniently and inexpensively since at least part of the thermal path is through the dielectric. Prior art leadless chip carriers that include a metal lid or a layer of metal underneath the chip mounting area are generally complex and expensive to manufacture and also often have limited heat dissipation capability. Furthermore, although the use of an external heat sink may increase heat dissipation, it is often difficult to attach or to provide sufficient space for a heat sink in conventional chip packaging modules.

Third, the adhesive material, commonly epoxy, used to secure a chip to a PCB in chip-on-board connections may “bleed out” under the chip and contaminate bond points on the PCB or other surface to which the chip is mounted. The bled out material may undesirably lead to short circuits. Consequently, additional steps must normally be taken to carefully regulate the dispensing of the material and/or to clean the PCB surface. The same bleed out problem may occur within a chip carrier package when a chip is secured to a chip mounting area using an adhesive material, possibly contaminating bond or connection points inside the carrier package.

Fourth, when two different materials have been soldered together, the difference in the thermal expansion characteristics between them often leads, after temperature cycling, to a fatiguing and cracking of the solder joint. Although the use of organic (as opposed to ceramic based) circuit substrates is becoming increasingly preferable due to their relative thinness, cost, and performance, thermal fatigue concerns often arise when a semiconductor chip is soldered to an organic substrate material (whether this occurs as a chip-on-board connection or to a carrier substrate as a packaging connection). For example, the coefficient of thermal expansion (CTE) of a silicon chip substrate is about 4 ppm /° C. and the CTE of GaAs chip substrate is about 6 ppm /° C., whereas typical organic chip carriers have a CTE in the range of 15-20 ppm /° C.—a significant mismatch. Although, for example, a ceramic substrate (having a CTE of about 6.5 ppm /° C.) may be used as a chip carrier substrate, a similar CTE mismatch may also arise when the ceramic carrier package is soldered or surface mounted to a next level organic circuit substrate. In addition, while an underfill of epoxy or other material may be used to help alleviate the mismatch between the coefficients of thermal expansion of two materials, this may only partly improve thermal fatigue performance and also may lead to bleed out concerns as described above. Therefore, despite the advantages of organic substrate materials, thermal fatigue concerns may render their use unreliable in connection with conventional chip interconnection techniques.

As a result, there is a need for a chip carrier that is capable of effectively protecting a semiconductor chip, is of relatively small size and profile, is minimally affected by electrical parasitics from bonding wires, provides an adequate heat conduction path to carry heat away from the chip during operation, and does not suffer from significant bleed out concerns. It would also be advantageous for such a package to conveniently enable a heat sink to be connected to it as well as for the package to provide good thermal fatigue performance for solder joints that connect the module to an organic circuit substrate.

### SUMMARY OF THE INVENTION

The present invention relates to a chip carrier suitable for inclusion in a semiconductor chip module. The chip carrier has a cavity portion for receiving a semiconductor chip, connected to a flange portion that is provided along at least a portion of the top perimeter of the cavity portion. The semiconductor chip module preferably also comprises a circuit substrate (e.g., a PCB, MCM substrate, or chip carrier substrate) having a slot extending through the substrate for receiving the cavity portion of the chip carrier, such that when the cavity portion of the chip carrier is inserted in the substrate slot, the flange portion of the chip carrier is supported by the substrate.

In one preferred embodiment, the flange portion of the chip carrier is electrically conductive and connected to a reference voltage level (e.g., ground), so that appropriate conductive pads on the chip, i.e., those that require connection to the reference potential, can be wire bonded directly to the flange. Preferably, the flange and cavity portions are each formed from the same metallic material (such as copper). The height of the cavity portion is selected to keep the length of the wire bonds short, i.e., so that the conductive bonding pads of the semiconductor chip are at approximately the same height as the flange portion of the chip carrier. The cavity portion is also preferably sized to tightly fit the chip, to further minimize the length of the wire bonds. Since the length of the wires is minimized, parasitic effects are minimized.

When the carrier is inserted within the substrate slot, the flange portion is preferably positioned above a reference conductive pad on a top surface of the substrate. The reference conductive pad, and thereby the flange portion, is connected to the desired reference voltage level, allowing very short wire bond lengths to be realized as described above since they only have to reach from the chip to the nearest point on the flange. The flange portion may be electrically and physically connected to the reference conductive pad by way of a solder connection. On-chip pads that are not connected to the flange may be wire bonded to a designated conductive pad on the surface of the circuit substrate. Advantageously, the length of these wires is also relatively short, so that their parasitic effects, if any, are also relatively small. An overmold of encapsulant material may be applied on the top surface of the substrate, over the chip carrier and the semiconductor chip.

The flange portion of the chip carrier preferably projects outwardly (although not preferred, in embodiments with appropriate geometry, it could also project inwardly) from the carrier and also preferably is substantially parallel to the bottom surface of the cavity portion. The cavity portion may have a substantially rectangular cross-section so that the top perimeter of the cavity portion has four sides, and, in that case, the flange portion is preferably provided along at least two opposing sides of the top perimeter. However, more preferably, the flange portion of the chip carrier is provided along the entirety of the top perimeter of the cavity portion of the chip carrier. Where the cavity and flange portions are formed from the same material, the carrier can be conveniently formed by stamping out the cavity portion from a single sheet of material, such as a sheet of copper.

In a preferred embodiment, the cavity portion of the chip carrier (and preferably the flange portion as well) is formed from a thermally conductive material. The semiconductor chip may also be secured to the bottom surface of the cavity portion by a thermally conductive adhesive material. In this manner, an efficient thermal path is provided to conduct heat away from the semiconductor chip during operation. A heat sink may further be connected underneath the cavity portion of the chip carrier to improve heat dissipation.

In another aspect, the present invention provides a semiconductor chip module comprising a chip mounting pad having a relatively thick body portion comprising a thermally conductive material and having a top surface. The mounting pad also has a flange portion connected to the body portion, the flange portion being provided around at least a portion of a perimeter of the body portion. A semiconductor chip is secured to the top surface of the body portion of the mounting pad. The module also includes a substrate having a slot for receiving the body portion of the chip mounting pad, so that when the chip mounting pad's body portion is inserted within the slot, the flange portion is supported by a top surface of the substrate. The body portion advantageously provides a very low thermal resistance path for conducting heat away from the chip.

### BRIEF DESCRIPTION OF THE DRAWINGS

The objects and advantages of the present invention will be better understood and more readily apparent when considered in conjunction with the following detailed description and accompanying drawings which illustrate, by way of example, preferred embodiments of the invention and in which:

FIG. 1 is a top view of a dish-shaped chip carrier in accordance with a preferred embodiment of the present invention;

FIG. 2 is a side view of the chip carrier of FIG. 1;

FIG. 3 is a top view of the chip carrier of FIG. 1 with a semiconductor chip inserted into the cavity portion of the carrier;

FIG. 4 is a cross-sectional view of the chip carrier with a semiconductor chip taken along the line IV-IV in FIG. 3; and

FIG. 5 is a top view of a circuit substrate having a slot for receiving the chip carrier;

FIG. 6 is a top view of the circuit substrate with the chip carrier inserted within the substrate slot;

FIG. 7 is a cross-sectional view of the circuit substrate and chip carrier taken along the line VII-VII in FIG. 6;

FIG. 8 is a cross-sectional view of a circuit substrate with the chip carrier inserted within a substrate slot in accordance with another embodiment of the present invention; and

FIG. 9 is a cross-sectional view of a circuit substrate with a chip mounting pad inserted within a substrate slot in accordance with still another embodiment of the present invention.

### DETAILED DESCRIPTION OF PREFERRED EMBODIMENTS

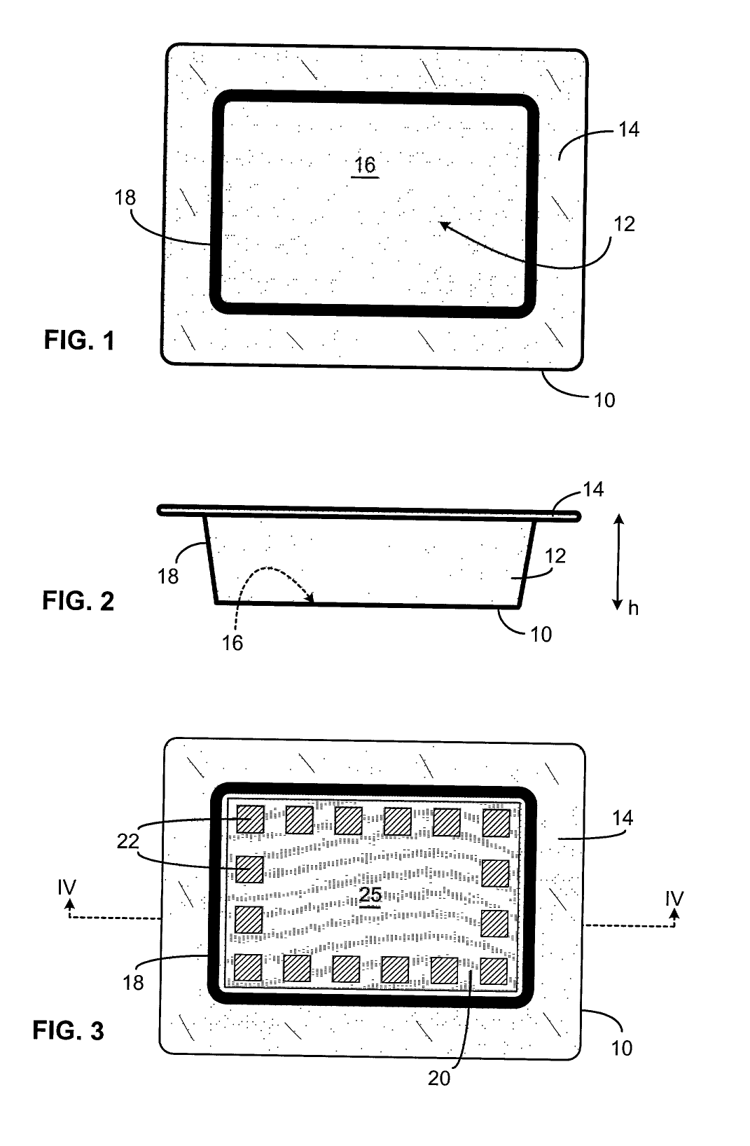

FIG. 1 is a top view of a “dish”-shaped chip carrier 10 in accordance with a preferred embodiment of the present invention. FIG. 2 is a side view of chip carrier 10 in FIG. 1. As shown, chip carrier 10 comprises a cavity portion 12 and a flange portion 14 provided along the upper perimeter of cavity portion 12. Cavity portion 12 has a bottom surface 16 and cavity side walls 18 that extend from surface 16 to meet flange portion 14.

Flange portion 14 is formed of an electrically conductive material. Cavity portion 12 is also preferably formed from an electrically conductive material, preferably the same material as flange portion 14. In a preferred embodiment, cavity portion 12 and flange portion 14 are both formed from a metallic material such as copper or aluminum that is also thermally conductive. Cavity portion 12 and flange portion 14 are also physically connected together. In a preferred embodiment, cavity portion 12 and flange portion 14 form an integral (i.e., one piece) chip carrier package, so that the electrical and thermal conductivity of chip carrier 10 is optimized. As described below chip carrier 10 may be used in combination with a substrate, having a hole sized to receive cavity portion 12, to form a semiconductor chip module.

As described in more detail below, the cross-sectional dimensions of cavity portion 12 (shown in the top view of FIG. 1) are preferably customized or selected to provide a relatively tight fit with a desired semiconductor device when the latter is inserted into cavity portion 12. As will be appreciated by those skilled in the art, a semiconductor chip or die typically has a rectangular (and often square) footprint, and so the cavity in the illustrated embodiment of FIG. 1 is also shown as being substantially rectangular. However, more generally, cavity portion 12 may be shaped to accommodate any semiconductor chip shape. In addition, the height, h, of cavity portion 12 is also selected based on the height of the semiconductor chip and the location of wire bonding pads on the chip, as explained further below.

As shown in FIG. 1, flange portion 14 preferably extends along the entire upper perimeter of cavity portion 12. However, flange portion 14 may alternatively only extend along a part of cavity portion 12's upper perimeter. For example, where cavity portion 12 is substantially rectangular, flange portion 14 may extend along two opposing sides of that perimeter. As also shown in FIG. 1, flange portion 14 preferably extends outwardly (i.e., away) from cavity portion 12. In a preferred embodiment, the surface of flange portion 14 is predominantly flat and generally parallel to bottom surface 16 of cavity portion 12, as may be seen in FIG. 2. Furthermore, as also illustrated in FIG. 2, side walls 18 of cavity portion 12 may be somewhat angled and are not necessarily vertical with respect to surface 16.

In a preferred embodiment, chip carrier 10 is conveniently formed by stamping out cavity portion 12 from a single sheet of material. For example, a sheet of copper having a thickness of about 0.05-0.1 mm may be stamped using standard machining and assembly procedures. Alternatively, cavity portion 12 and flange portion 14 may be separately formed and then welded or otherwise connected together to form chip carrier 10.

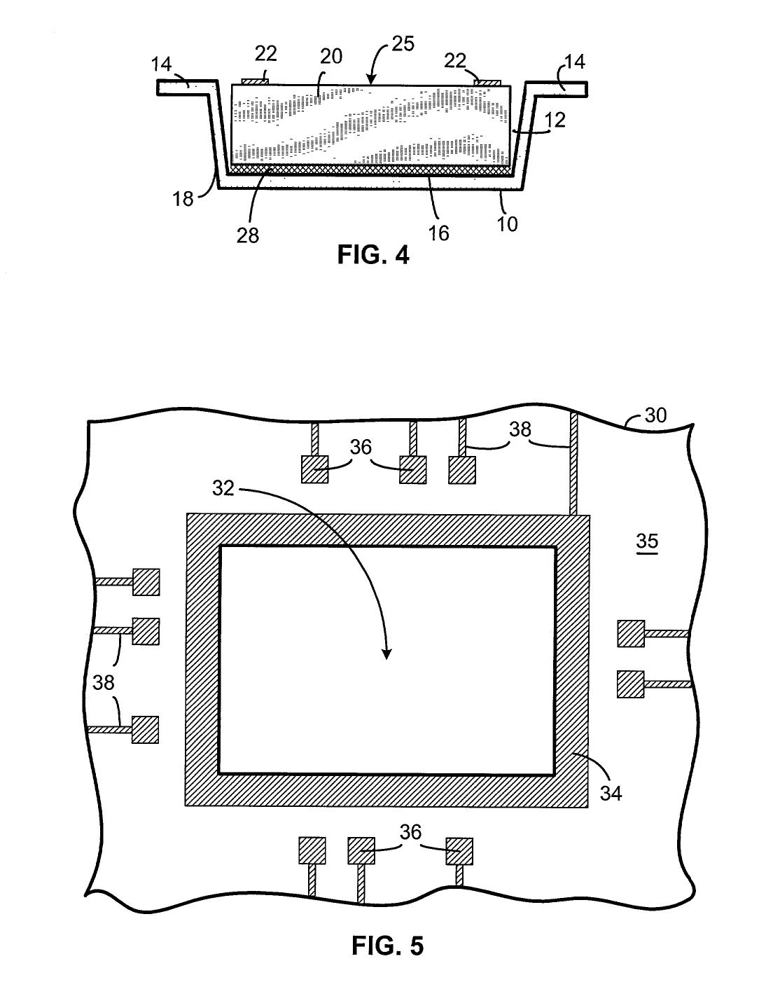

FIG. 3 shows a top view of chip carrier 10 with a semiconductor chip 20, typically an integrated circuit die, inserted into cavity portion 12. FIG. 4 is a cross-sectional view of the chip carrier and semiconductor chip taken along the line IV-IV in FIG. 3. As shown in FIGS. 3 and 4, semiconductor chip 20 preferably has one or more wire bonding pads 22 on a top surface 25 of the chip. Although chip 20 could alternatively or additionally have wire bonding pads on the side surfaces of chip 20, it is preferred that all of chip 20's wire bonding pads lie on top surface 25. As will be appreciated, each bond pad 22 on chip 20 typically represents an input or output node in an integrated circuit, and pads 22 generally require an off-chip connection to receive or provide an electrical signal during operation of the integrated circuit.

As illustrated in FIG. 4, chip 20 is secured to bottom surface 16 of cavity portion 12 using an adhesive material 28, preferably a thermal adhesive such as silver-filled epoxy. As shown, the height of cavity portion 12 is preferably selected so that, once chip 20 is secured in cavity portion 12, on-chip bonding pads 22 are at approximately the same height as flange portions 14 of carrier 10. This helps minimize the distance between bonding pads 22 and flange portion 14. Furthermore, chip 20 preferably fits tightly into cavity portion 12 to further minimize that distance. In a typical embodiment, spacing of the order of 0.1 mm may be provided between chip 20 and side walls 18. The bleeding out of material 28 underneath chip 20 is generally not a concern since electrical connections are not made on the surface 16 of dish 10, other than possibly an electrical connection of the chip substrate to dish 10 through material 28. (Furthermore, since there is only a small space or distance between semiconductor chip 20 and side walls 18 of cavity portion 12, particularly near the bottom of the cavity, material 28 typically has little or no space to bleed out from underneath chip 20.)

FIG. 5 is a top view of a circuit substrate 30 having a slot or hole 32 for receiving the cavity portion of chip carrier 10 in accordance with a preferred embodiment of the present invention. Substrate 30 comprises a base substrate material having a number of conductive pads and conductive lines (or traces) on a surface 35 thereof. The base substrate material may be any suitable inorganic material such as ceramic, or it may be any suitable organic material such as a BT (bismaleimide-triazone) resin laminate, FR-4 or -5 (flame retardant -4 or -5), or GETEK™. The conductive pads on circuit substrate 30 are used to provide a first level of electrical connections from semiconductor chip 20. Thus, for instance, substrate 30 may be a MCM substrate or a printed circuit board (PCB) and may connect semiconductor chip 20 to other chips, components, and/or supply signals that are also provided on substrate 30. Alternatively, and as described further below in connection with FIG. 8, the substrate in combination with carrier 10 may form a single chip packaging module that facilitates a second level of electrical connections to a further (and usually larger) circuit substrate.

Referring to FIG. 5, on substrate surface 35 a conductive pad 34 is shown extending around the perimeter of slot 32. When chip carrier 10 is inserted into substrate slot 32, flange portion 14 of carrier 10 is supported by surface 35 of substrate 30. More particularly, conductive pad 34 is shaped and positioned on surface 35 so that flange portion 14 is positioned above conductive pad 34 to enable a physical and electrical connection between flange portion 14 and conductive pad 34, preferably using solder. Where flange portion 14 only extends along a portion of the upper perimeter of cavity portion 12, conductive pad 34 preferably only extends along a corresponding portion of the perimeter of substrate slot 32. Furthermore, since flange portion 14 comprises an electrically conductive material, it will be appreciated that conductive pad 34 need not extend around an entire corresponding portion of the perimeter of slot 32, but rather pad 34 generally need only extend around a portion of the slot 32 perimeter that is sufficient to provide a physical and electrical connection with flange portion 14. On surface 35, circuit substrate 30 also comprises a number of additional conductive pads 36 spaced around substrate slot 32, but at a greater distance from slot 32 than pad 34. Conductive pad 34 and each conductive pad 36 may include a conductive line or trace 38 that runs along (as shown in FIG. 5) and/or underneath substrate surface 35.

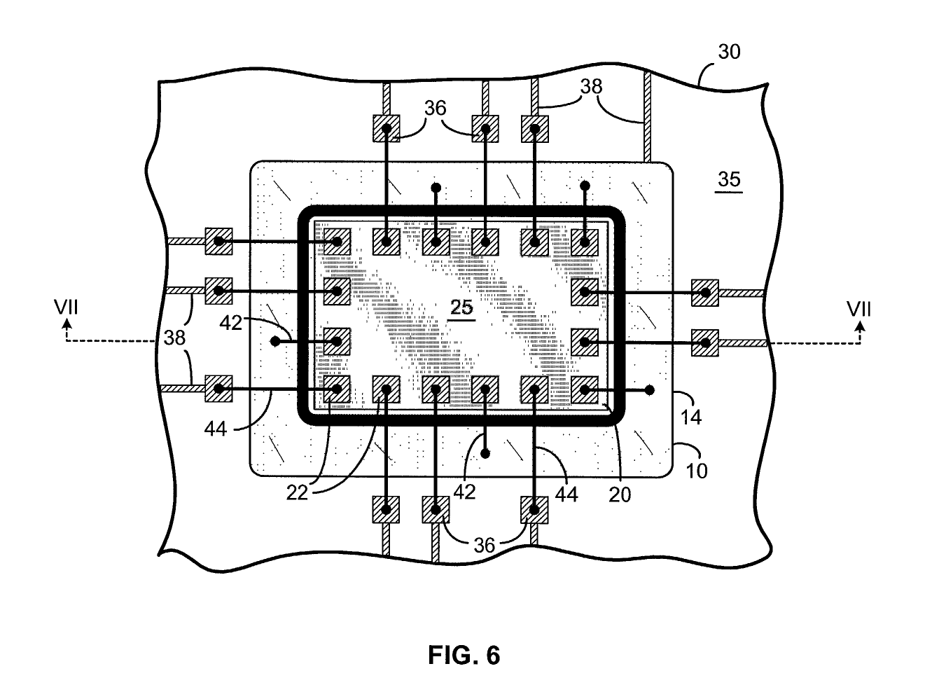

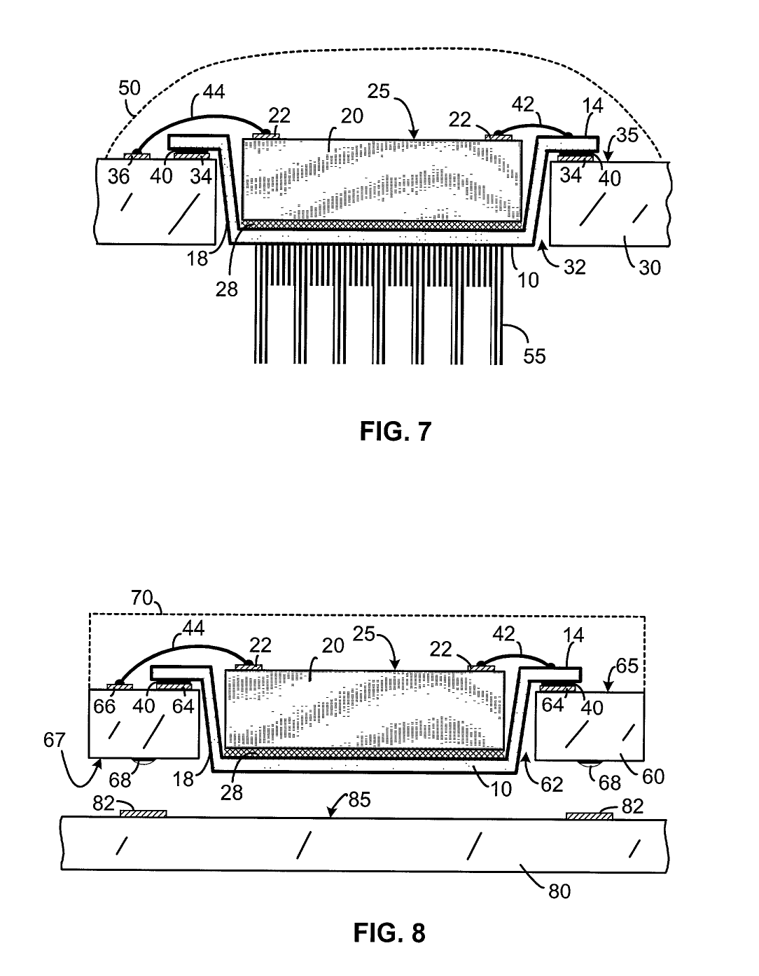

FIG. 6 is a top view of circuit substrate 30 after chip carrier 10 (with semiconductor chip 20 secured therein) has been inserted within substrate slot 32. FIG. 7 is a cross-sectional view of chip carrier 10 in substrate 30, taken along the line VII-VII in FIG. 6. Referring to FIGS. 6 and 7, flange portion 14 is preferably electrically connected to conductive pad 34, and physically connected to substrate 30, preferably using a solder material 40, such as a near-eutectic Sn—Pb (tin-lead) solder alloy. Alternatively, an interconnect material such as conductive epoxy may be used instead of solder 40. In accordance with the embodiment of FIGS. 6 and 7, during electrical operation, conductive pad 34 is connected to a reference voltage, such as a ground voltage or a negative supply voltage (e.g., Vss), so that flange portion 14 is also held at the reference voltage level. As indicated, cavity portion 12 is preferably electrically conductive so that cavity portion 12 (and the entire chip carrier 10 generally) is also held at the reference voltage. In this case, where the adhesive material 28 used to secure chip 20 in cavity portion 12 is electrically conductive, an electrical connection between the substrate of chip 20 and chip carrier 10 also results.

As indicated, flange portion 14 is preferably formed from a conductive metal such as copper, which has a CTE of about 17 ppm/° C., or aluminum, which has a CTE of about 23 ppm/° C. Thus, where substrate 30 comprises an organic base material, solder joint 40—or solder joints 40 if separate joints 40 are formed—connecting flange portion 14 to substrate 30 (through pad 34) generally undergoes a low amount of thermal fatigue stress when temperature cycled. As described above, this is as a result of the relatively close matching of the CTEs of the materials, since the CTE of organic substrates is typically within the range of 15-20 ppm/° C. On the other hand, if substrate 30 comprises, for example, a ceramic substrate, an underfill of epoxy or other suitable material may be used to help avoid any thermal fatiguing of solder joint(s) 40. As a further alternative, conductive epoxy may be used in place of solder joint 40.

Referring to FIG. 6, each bond pad 22 on chip 20 that is to be connected to the reference voltage during operation of the integrated circuit in chip 20 is electrically connected via a wire 42 to flange portion 14 of chip carrier 10 (and thereby to pad 34 on substrate 30). Thus, flange portion 14 is preferably provided at least around those portions of the upper perimeter of cavity portion 12 that are near chip pads 22 requiring a connection to flange 14, i.e., to the ground or reference voltage. Other bond pads 22 on chip 20 that provide or receive electrical signals are each connected by way of a wire 44 to a corresponding pad 36 on substrate 30 to provide a necessary input or output in the integrated circuit of chip 20. The connection of wires 42 and 44 may be carried out using any suitable wire bonding technique such as thermal compression bonding, ultrasonic bonding, or pulse bonding. Wires 42 and 44 are preferably formed from gold or aluminum and may, for example, have a diameter in the range of 0.025 mm to about 0.4 mm, depending on the size and type of semiconductor chip 20.

As is most clearly shown in the cross-sectional view of FIG. 7, the lengths of bond wires 44 and particularly of bond wires 42 are kept small since, as described above, on-chip bonding pads 22 are at approximately the same height as flange portions 14 (and also roughly the same height as conductive pads 36 on substrate surface 35). The tight fit of chip 20 within cavity portion 12 further helps to reduce the length of the wires. As a result, the high frequency parasitic effects from wires 42 and 44 are maintained at a low or minimal level.

In the illustrated embodiment of FIGS. 6 and 7, circuit substrate 30 may be a MCM substrate, a PCB, or the like having other semiconductor chips (in addition to chip 20) mounted upon it, as indicated above. For example, substrate 30 may act as a multi-chip module (MCM) substrate with the assembly of chip 20 in carrier 10 acting as a sub-module within the larger MCM. Other chips may be directly surface mounted to substrate 30, or, if desirable, they may also be mounted onto substrate 30 as a sub-module, in the same manner as chip 20. In this embodiment, a module comprising semiconductor chip 20 in carrier 10 is preferably glob top molded with an encapsulant material, as indicated by the broken line 50 in FIG. 7. Similar to chip-on-board connections, the encapsulant material may be a non-conductive plastic that protects chip 20 and wire bonds 42 and 44. The encapsulant material also preferably has a low coefficient of thermal expansion so that ambient temperature changes do not loosen the wire bonds being protected.

As indicated, chip carrier 10, in particular cavity portion 12 thereof, is preferably formed from a thermally conductive material. Material 28 used to secure chip 20 to cavity portion 12 is also preferably a thermal adhesive material. As a result, chip carrier 10 provides an effective heat conduction path to directly carry heat away from chip 20 during operation. To aid in the dissipation of heat from carrier 10, a heat sink 55 may be attached to carrier 10, at the base of cavity portion 12, as shown in FIG. 7. Heat sink 55 may, for example, be attached to carrier 10 using a solder or a thermal adhesive (the thermal adhesive may again be silver-filled epoxy). Alternatively, in this embodiment, heat sink 55 may be integrally formed with chip carrier 10 to further improve thermal conduction.

Similar to FIG. 7, FIG. 8 is a cross-sectional view of carrier 10 (with semiconductor chip 20 secured therein) after the carrier has been inserted within a slot 62 in a substrate 60. In the embodiment of FIG. 8, a first level of connections from on-chip pads 22 to conductive pads 64 and 66 on a surface 65 of substrate 60 is made in the same manner as described above in connection with FIGS. 6 and 7. However, in this embodiment, substrate 60 and chip carrier 10 together form a single-chip packaging module (similar in purpose to a conventional chip carrier package) that may be mounted, in a second level of electrical connections, on to a surface 85 of another circuit substrate 80.

To facilitate electrical connection with next level circuit substrate 80, chip carrier substrate 60 preferably comprises conductive balls or bumps 68 on a bottom surface 67 thereof. Balls 68 may be soldered to conductive pads 82 on surface 85 of substrate 80, to surface mount the carrier package. Instead of balls 68, substrate 60 could alternatively be provided with terminal leads that are surface mounted onto circuit substrate 80. As a further option, the chip carrier package formed by carrier 10 and substrate 60 may be mounted to a circuit substrate 80 using through-hole mounting techniques. Electrical vias (not shown) in substrate 60 may be used to connect conductive pads 64 and 66 on surface 65 to conductive balls 68 (or to another type of terminals) on surface 67.

As described above, chip carrier 10, particularly bottom surface 16, provides an effective heat conduction path to directly carry heat away from chip 20 during operation. As a result, in the embodiment of FIG. 8, circuit substrate 80 preferably provides good thermal conduction so that heat from carrier 10 can effectively dissipate into and through substrate 80. Furthermore, in a preferred embodiment, the base of chip carrier 10 is soldered or thermally adhered directly to the surface 85 of next level substrate 80 to improve thermal conduction into substrate 80. Where, as is preferred, cavity portion 12 is electrically conductive and is also held at the ground or reference voltage level, the base of cavity portion 12 may be soldered to a large conductive pad on surface 85 of substrate 80 that is also connected to that voltage level. Alternatively, the base of cavity portion 12 may be soldered directly to the insulating base material of circuit substrate 80. In addition, the chip carrier package comprising chip carrier 10 and substrate 60 may also be provided with a cap or lid, as indicated by broken line 70 in FIG. 8. The cap may be formed of ceramic, for example.

One again, where substrate 60 comprises an organic base material, a solder joint connecting carrier 10's flange portion 14 to substrate 60 generally undergoes minimal thermal fatiguing when temperature cycled due to the relatively close matching of the CTEs of the flange portion 14 and substrate 60 materials. Conveniently, next level circuit substrate 80 may also be organic based, so that when solder joints are used to surface mount substrate 60 (along with carrier 10) to circuit substrate 80, those solder joints also undergo limited thermal fatiguing after temperature cycling.

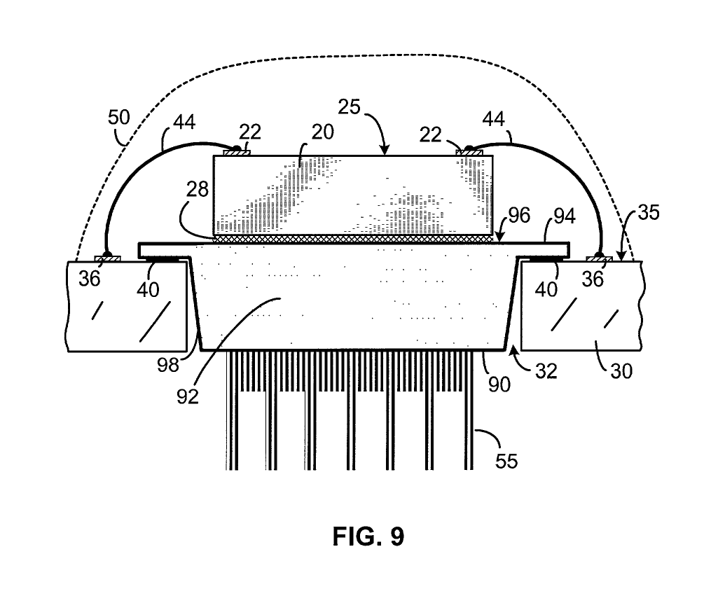

In accordance with another embodiment of the present invention, FIG. 9 provides a cross-sectional view of a circuit substrate in which, instead of “dish”-shaped carrier 10, a generally flat chip mounting pad 90 is inserted within the slot 32 of substrate 30. Chip mounting pad 90 has a solid, relatively thick thermally conductive main body portion 92 having a top surface 96 on which chip 20 is mounted. In a preferred embodiment, the thickness of body portion 92 i approximately the same as the thickness of substrate 30. Chip 20 is preferably secured to mounting pad 90 by way of a thermal adhesive material 28, and a module comprising chip 20 on pad 90 may be glob top molded with an encapsulant material, as indicated at 50. Mounting pad 90 also comprises a relatively thin flange portion 94 connected to the body portion and extending outwardly from the body portion, preferably at or near the top of body portion 92, as shown in FIG. 9. The upper surface of flange portion 94 preferably lies flush with the upper surface 96 of body portion 92. The flange portion 94 preferably extends along the entire perimeter of body portion 92 but may alternatively extend around only part of the perimeter of main body portion 92. For example, where body portion 92 (and surface 96) is substantially rectangular, flange portion 94 may extend along two opposing sides of the chip mounting pad body. Flange portion 94 is preferably formed from the same material as body portion 92, and more preferably both portions comprise copper. It is further preferred that body portion 92 and flange portion 94 are integrally formed as a single component.

As with the modules of FIGS. 7 and 8, flange portion 94 is physically connected to substrate 30 to support pad 90 within slot 32. Again, this connection may be made using a solder material 40 or alternatively an adhesive such as epoxy. In the illustrated embodiment of FIG. 9, all bonding pads 22 on the top surface of chip 20 are wire bond connected to pads 36 on the surface 35 of substrate 30. Thus, unlike in the embodiments of FIGS. 7 and 8, wires for connecting certain on-chip pads 22 to a reference voltage level are not bonded to the flange portion 94, but instead to appropriate bonding pads 36 on substrate 30. Thus, in this embodiment, it is not generally necessary to provide one or more conductive pads 34 on the substrate surface 35, underneath flange portion 94 (although this may still be desirable if mounting pad 90 including flange portion 94 are both electrically conductive and are to be connected to ground). Alternatively, wire bond connections for a reference voltage may be made to flange portion 94 in a manner similar to that described in connection with FIGS. 7 and 8 above. However, in this case, any bleed out of material 28 on surface 96 is preferably contained to avoid possible contamination of bonding points on flange 94.

Due to the relatively large thickness of chip mounting pad 90 in the embodiment of FIG. 9, a heat conduction path with very low thermal resistance is provided from chip 20 through pad 90. Furthermore, as shown, an additional heat sinking component 55 may be attached to the lower surface of body portion 92 to provide improved heat dissipation. The embodiment of FIG. 9 is thus particularly suitable for high power semiconductor chips that generate significant amounts of heat. As will be appreciated, the length of wire bond connections 44 in this embodiment may be longer and therefore may potentially induce greater parasitic effects than in the other embodiments described above. To reduce the length of wire bond connections in the embodiment of FIG. 9, on-chip bonding pads 22 may optionally be provided along one or more side surfaces of chip 20. Furthermore, the substrate 30 in FIG. 9 may also be mounted, in a second level of electrical connections, on to another circuit substrate, in a manner similar to that described in connection with the embodiment of FIG. 8.

While the invention has been described in conjunction with specific embodiments, it is evident that numerous alternatives, modifications, and variations will be apparent to those skilled in the art in light of the foregoing description.

What is claimed is:

1. A semiconductor chip module comprising:
a chip carrier having a cavity portion connected to a flange portion, the flange portion being provided along at least a portion of a top perimeter of the cavity portion;
a semiconductor chip having one or more conductive bonding pads on a surface thereof, the semiconductor chip being secured to a bottom surface of the cavity portion of the chip carrier; and
a substrate having a slot for receiving the cavity portion of the chip carrier, wherein when the cavity portion of the chip carrier is inserted within the slot, the flange portion of the chip carrier is supported by a top surface of the substrate.

2. The module of claim 1 wherein at least one of the one or more conductive bonding pads on the semiconductor chip is wire bonded to a designated conductive pad on the top surface of the substrate.

3. The module of claim 2 wherein the designated conductive pad on the top surface of the substrate is connected to a corresponding electrical terminal on a bottom surface of the substrate to facilitate electrical and physical connection of the module to a second substrate.

4. The module of claim 1 wherein the semiconductor chip is secured to the bottom surface of the cavity portion by an adhesive material, and wherein the cavity portion is sized such that the semiconductor chip is closely spaced to walls of the cavity portion.

5. The module of claim 1 wherein the cavity portion is sized such that the one or more conductive bonding pads of the semiconductor chip are at approximately the same height as the flange portion of the chip carrier.

6. The module of claim 1 further comprising a cap provided on the top surface of the substrate over the chip carrier and the semiconductor chip.

7. The module of claim 1 wherein the cavity portion and the flange portion of the chip carrier are each formed from an electrically conductive material.

8. The module of claim 7 wherein at least one of the one or more conductive bonding pads of the semiconductor chip is wire bonded to the flange portion of the chip carrier.

9. The module of claim 7 wherein each of the conductive bonding pads of the semiconductor chip that is wire bonded to the flange portion of the chip carrier corresponds to a node in an integrated circuit in the semiconductor chip that is to be connected to a reference voltage level during operation of the integrated circuit.

10. The module of claim 1 wherein the flange portion of the chip carrier is connected to the substrate by way of a solder connection.

11. The module of claim 10 wherein the substrate comprises an organic base material.

12. The carrier of claim 25 wherein the cavity portion of the chip carrier is formed from a thermally conductive material.

13. The module of claim 12 wherein the semiconductor chip is secured to the bottom surface of the cavity portion by a thermally conductive adhesive material.

14. A semiconductor chip module comprising:
a chip carrier having a cavity portion connected to a flange portion, the flange portion being provided along at least a portion of a top perimeter of the cavity portion, the flange portion further being formed from an electrically conductive material; and
a semiconductor chip having one or more conductive bonding pads on a surface thereof, the semiconductor chip being secured to a bottom surface of the cavity portion of the chip carrier.

15. The module of claim 14 wherein the flange portion of the chip carrier is provided along the entirety of the top perimeter of the cavity portion of the chip carrier.

16. The module of claim 14 wherein the cavity portion of the chip carrier is also formed from an electrically conductive material.

17. The module of claim 16 wherein the cavity portion and the flange portion are each formed from the same material.

18. The module of claim 17 wherein the cavity portion and the flange portion both comprise copper.

19. The module of claim 14 wherein the semiconductor chip is secured to the bottom surface of the cavity portion by an adhesive material.

20. The module of claim 19 wherein the cavity portion is sized such that the semiconductor chip is closely spaced to walls of the cavity portion.

21. The module of claim 14 wherein the one or more conductive bonding pads of the semiconductor chip are located on a top surface of the semiconductor chip.

22. The module of claim 14 wherein the cavity portion is sized such that the one or more conductive bonding pads of the semiconductor chip are at approximately the same height as the flange portion of the chip carrier.

23. The module of claim 14 wherein at least one of the one or more conductive bonding pads of the semiconductor chip is wire bonded to the flange portion of the chip carrier.

24. The module of claim 23 wherein the cavity portion is sized such that the one or more conductive bonding pads of the semiconductor chip are at approximately the same height as the flange portion of the chip carrier.

25. The module of claim 23 wherein each of the conductive bonding pads of the semiconductor chip that is wire bonded to the flange portion of the chip carrier corresponds to a node in an integrated circuit in the semiconductor chip that is to be connected to a reference voltage level during operation of the integrated circuit.

26. The module of claim 25 wherein the reference voltage level is a ground voltage in the integrated circuit.

27. The module of claim 25 further comprising a substrate having a slot for receiving the cavity portion of the chip carrier, wherein when the cavity portion of the chip carrier is inserted within the slot, the flange portion of the chip carrier is supported by the substrate.

28. The module of claim 27 wherein when the cavity portion of the chip carrier is inserted within the slot, the flange portion of the chip carrier is positioned above a reference conductive pad on a top surface of the substrate.

29. The module of claim 28 wherein the flange portion is electrically and physically connected to the reference conductive pad on the substrate by way of a solder connection.

30. The module of claim 29 wherein the substrate comprises an organic base material.

31. The module of claim 28 wherein the reference conductive pad on the substrate is also connected to a reference voltage level during operation of the integrated circuit.

32. The module of claim 28 wherein the semiconductor chip comprises a plurality of conductive bonding pads, at least one of which is wire bonded to a designated conductive pad on the top surface of the substrate and not to the flange portion of the chip carrier.

33. The module of claim 27 wherein the cavity portion of the chip carrier is formed from a thermally conductive material.

34. The module of claim 33 wherein the flange portion of the chip carrier is formed from the same thermally conductive material as the cavity portion.

35. The module of claim 33 wherein the semiconductor chip is secured to the bottom surface of the cavity portion by a thermally conductive adhesive material.

36. The module of claim 35 further comprising a heat sink connected to the cavity portion of the chip carrier.

37. The module of claim 27 further comprising an overmold of encapsulant material provided on the top surface of the substrate over the chip carrier and the semiconductor chip.

38. A carrier for a semiconductor chip comprising:
a cavity portion for receiving a chip on a bottom surface thereof,
a flange portion provided along at least a portion of a top perimeter of the cavity portion;
wherein the flange portion is formed from an electrically conductive material and is connected to the cavity portion.

39. The carrier of claim 38 wherein the flange portion projects outwardly from the carrier.

40. The carrier of claim 38 wherein the flange portion is substantially parallel to the bottom surface of the cavity portion.

41. The carrier of claim 38 wherein the cavity portion has a substantially rectangular cross-section so that the top perimeter of the cavity portion has four sides.

42. The carrier of claim 41 wherein the flange portion is provided along at least two opposing sides of the top perimeter of the cavity portion.

43. The carrier of claim 38 wherein the flange portion is provided along the entirety of the top perimeter of the cavity portion.

44. The carrier of claim 38 wherein the cavity portion is formed from a thermally conductive material.

45. The carrier of claim 38 wherein the cavity portion and the flange portion are each formed from the same material.

46. The carrier of claim 45 wherein the cavity portion and the flange portion each comprise copper.

47. The carrier of claim 38 wherein the carrier is formed by stamping out the cavity portion from a single sheet of material.

48. A semiconductor chip module comprising:
a chip mounting pad comprising
a body portion having a top surface and comprising a thermally conductive material, and
a flange portion connected to said body portion, the flange portion being provided around at least a portion of a perimeter of the body portion;
a semiconductor chip secured to the top surface of the body portion of the chip mounting pad; and
a substrate having a slot for receiving the body portion of the chip mounting pad, wherein when the body portion of the chip mounting pad is inserted within the slot, the flange portion of the chip mounting pad is supported by a top surface of the substrate.

49. The module of claim 48 wherein the flange portion of the chip mounting pad has a top surface substantially flush with the top surface of the body portion of the chip mounting pad.

50. The module of claim 48 wherein the semiconductor chip has one or more conductive bonding pads on a surface thereof, and at least one of the one or more conductive bonding pads on the semiconductor chip is wire bonded to a designated conductive pad on the top surface of the substrate.

51. The module of claim 48 wherein the body portion and the flange portion of the chip mounting pad each comprise copper.

52. The module of claim 48 wherein the flange portion of the chip mounting pad is connected to the substrate by way of a solder connection.

53. The module of claim 48 wherein the substrate comprises an organic base material.

54. The module of claim 48 wherein the semiconductor chip is secured to the top surface of the body portion by a thermally conductive adhesive material.

55. The module of claim 48 further comprising a heat sink connected to a bottom surface of the body portion of the chip mounting pad.
